(19) United States
(12) Patent Application Publication
(10) Pub. No.: US 2003/0021225 A1
(43) Pub. Date: Jan. 30, 2003

(54) Method for providing an equivalent circuit for transmission devices in ring architectures that route mpls packets

(76) Inventor: Joachim Klink, Muenchen (DE)

Correspondence Address: MORRISON & FOERSTER LLP, 1650 TYSONS BLVD. - SUITE 300, MCLEAN, VA, 22102, US

(21) Appl. No.: 10/204,975

(22) PCT Filed: Jan. 12, 2001
(86) PCT No.: PCT/EP01/00338

(30) Foreign Application Priority Data
Feb. 29, 2000 (EP) 00104146.6

(51) Int. Cl. G01R 31/08; H04L 12/28

(52) U.S. Cl. 370/222; 370/400

(57) ABSTRACT

In prior art, the provision of an equivalent circuit for ATM cells is efficiently controlled using linear structures. According to the invention, in order to also transit these structures to ring-type architectures, a ring-type structure is configured from linear structures as follows: additional linear structures are integrated into the transmission section of a linear structure and the switching devices of the original linear structure are combined. In addition, a large number of equivalent circuits share a common reserved transmission capacity.

### CLAIM FOR PRIORITY

This application claims priority to International Application No. PCT/EP01/00338 which was published in the German language on Sep. 7, 2001.

### TECHNICAL FIELD OF THE INVENTION

The invention relates to a method for the protection switching of transmission devices in ring-type architectures carrying MPLS packets.

### BACKGROUND OF THE INVENTION

A method for the protection switching of transmission devices in ring-type architectures is disclosed in German patent application DE 197 039 92.8.

This method relates to transmission devices via which information is conducted in accordance with an asynchronous transfer mode (ATM). In this arrangement, transmission devices for the bidirectional transmission of information is/are provided in which two switching devices acting as terminal stations are connected to one another via a multiplicity of operating links and one protection link. The two terminal stations in each case contain monitoring devices for detecting transmission disturbances. A switching system, which can be controlled by a monitoring device, connects a receiving device to the operating link in a first switching state and to the protection link in a second switching state.

The disadvantageous factor of this method is that it relates exclusively to ATM transmission devices. In the Internet, information is supplied to the receiving subscriber via a multiplicity of network nodes which can be constructed as routers. Between the routers, MPLS networks can be arranged. However, there is no mention whatsoever of MPLS networks in the known method.

### SUMMARY OF THE INVENTION

The invention discloses a method having information which is transmitted in accordance with an Internet protocol can be transmitted with great reliability over a multiplicity of network nodes.

One advantageous factor in the invention is that a multiplicity of protection links share a jointly reserved transmission capacity.

### BRIEF DESCRIPTION OF THE DRAWINGS

In the text which follows, the invention will be explained in more detail with reference to exemplary embodiments.

In the figures:

FIG. 1 shows an MPLS network linked in to the Internet.

FIG. 2 shows a configuration for the bidirectional transmission of ATM cells in a linear 1:1 structure.

FIG. 3 shows a ring-shaped configuration in which the method according to the invention is run.

FIG. 4 shows the method according to the invention in the case of a simple fault.

FIG. 5 shows the method according to the invention in the case of a double fault.

### DETAILED DESCRIPTION OF THE PREFERRED EMBODIMENTS

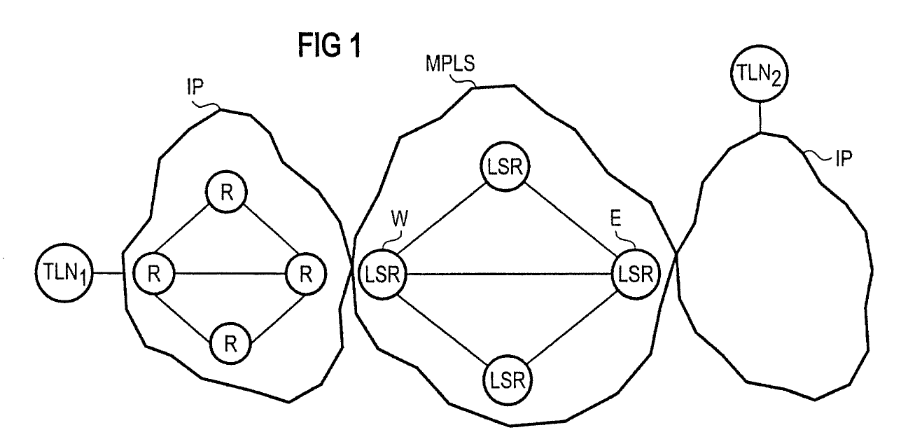

FIG. 1 shows by way of example how information coming from a subscriber TLN1 is supplied to a subscriber TLN2. The transmitting subscriber TLN1 is connected to the Internet network IP through which the information is conducted in accordance with an Internet protocol such as, e.g., the IP protocol.

This protocol is not a connection-oriented protocol. The Internet network IP exhibits a multiplicity of routers R which can be intermeshed with one another. The receiving subscriber TLN2 is connected to a further Internet network IP. Between the two Internet networks IP, an MPLS (Multiprotocol Packet Label Switching) network is inserted through which information is switched through in a connection-oriented manner in the form of MPLS packets. This network exhibits a multiplicity of mutually intermeshed routers. In an MPLS network, these can be so-called label switched routers (LSR). One of the routers is designated as transmitting device W and another one is designated as receiving device E.

MPLS packets in each case have a header (packet header) and an information section. The header is used for accommodating connection information whereas the information section is used for accommodating user information. The user information used is IP packets. The connection information included in the header is arranged as MPLS connection number. However, this has validity in the MPLS network. When thus an IP packet from the Internet network IP penetrates into the MPLS network, the header valid in the MPLS network is appended to it. This includes connection information which predetermines the path of the MPLS packet in the MPLS network. If the MPLS packet leaves the MPLS network, the header is removed again and the IP packet is routed further as determined by the IP protocol in the Internet network IP following it.

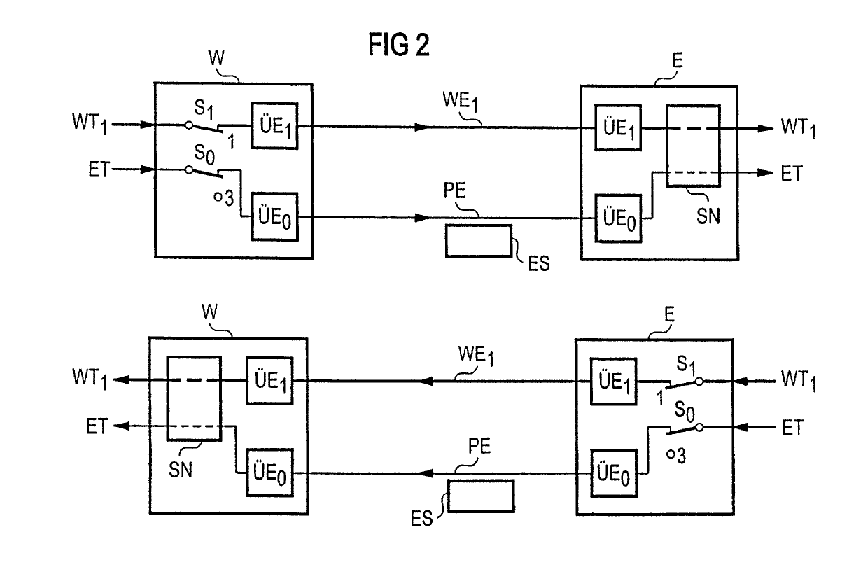

FIG. 2 shows by way of example two nodes of an MPLS network in a linear configuration which are in each case arranged as switching device W, E. This is a 1:1 structure. In the present exemplary embodiment, it is assumed that these switching devices are MPLS cross-connect switching or label switched routers. Using switching devices of such a construction, however, does not signify a restriction of the invention and other switching devices such as, e.g., ATM switching devices can similarly be used. In FIG. 2, MPLS (Multiprotocol Label Switched) packets are then to be transmitted from the label switched router W to the label switched router E.

In FIG. 2, a case of bidirectional transmission is shown. However, the transmission of MPLS packets in the MPLS network is defined as being unidirectional. Accordingly, a total of two “connections” (one for the forward direction and one for the reverse direction) must be set up for the forward and reverse transmission of MPLS packets, belonging to a connection WT, between the label switched router W and the label switched router E in the case of bidirectional transmission. A “connection” in the MPLS network is called a Label Switched Path (LSP).

The label switched routers W, E are connected to one another via operating links (WORKING ENTITY), which according to the present exemplary embodiment are to be configured as a single operating link WE₁, and one protection link PE (PROTECTION ENTITY). Furthermore, switching systems S₀, S₁ (BRIDGE) are shown via which the incoming MPLS packets are optionally transmitted toward the label switched router E via the operating link WE₁ or the protection link PE.

Furthermore, FIG. 2 shows selection devices SN, the task of which is to supply the MPLS packets transmitted via the operating link WE₁ to the output of the label switched router E. The selection devices SN are constructed as switching network. The switching network SN is contained both in the label switched router W and in the label switched router E.

Furthermore, monitoring devices ÜE₀, ÜE₁ (PROTECTION DOMAIN SINK, PROTECTION DOMAIN SOURCE) which monitor the state or the quality of the MPLS packets transmitted via the operating link WE₁ are shown in the two label switched routers W, E. For example, the MPLS packets of the connection with the number 1 WT₁, before they are transmitted via the operating link WE₁ toward the label switched router E, are provided with control information in the monitoring device ÜE₁ of the label switched router W, which control information is extracted and checked by the monitoring device ÜE₁ of the receiving label switched router E. Using this control information, it is then possible to determine whether the transmission of the MPLS packets has been correct or not. In particular, a total failure (SIGNAL FAIL FOR WORKING ENTITY) of the operating link WE₁ can be determined here. Similarly, degradations in the transmission quality (SIGNAL DEGRADE) however can also be determined by using known methods.

The monitoring device ÜE₁ terminate the operating link WE₁ at both ends. Other monitoring devices ÜE₀ are arranged at both ends of the protection link PE. In the case of a fault, this is to be used as transmission link for the operating link WE₁ taken out of operation. Furthermore, protection switching protocols ES are transmitted via this link so that the integrity of the protection link has top priority.

In each of the label switched routers W. E, central controllers, not shown in FIG. 2, are also arranged. These include in each case local and global priority tables. In the case of the former, status and priority of the local label switched router is stored whereas in the case of the latter, status and priority both of the local and of the remaining label switched routers are stored. The introduction of the priorities has the result that when a number of protection switching requests occur at the same time, the link is specified which is to be protection-switched. Similarly, the protection switching requests are prioritized in the priority tables. Thus, for example, there is a high-priority request from a user. Since this protection switching request is assigned a high priority, it is thus controlled with preference. A protection switching request controlled by the operating link WE₁ will then be rejected in this case.

The central controllers of the label switched routers W. E exchange information in a protection switching protocol ES. This protocol is transmitted via the protection link PE and extracted by the associated monitoring device ÜE₀ from the respective receiving label switched router E, and supplied to the relevant central controller. Furthermore, the central controller ensures that the switching systems S₀, S₁ are appropriately controlled in the case of a fault.

In the protocol ES, information relating to the current states of the switching systems is stored. Furthermore, other information with respect to the protection switching request generated is also stored. The protocol is in each case exchanged between the two label switched routers when the protection switching request is generated. In a special embodiment of the invention, there is provision for the protocol ES to be additionally transmitted cyclically between the two label switched routers.

According to FIG. 2, the MPLS packets are supplied to the label switched router E in the case of correct operation. The MPLS packets are to belong to the connection WT₁ in this case. The individual connections are distinguished by means of the logical MPLS connection number entered in the packet header.

In this (still correct) operating case, the switching systems S₀, S₁ of the label switched router W are switched in such a manner that the MPLS packets are directly supplied to the monitoring device ÜE₁. In the latter, the control information already discussed is applied to the receiving label switched router E to the MPLS packets and they are supplied to the receiving label switched router E via the operating link WE₁ of the monitoring devices ÜE₁. At the label switched router E the accompanying control information is checked and, if appropriate, a fault case is determined. If the transmission has been correct, the MPLS packets are supplied to the switching network SN, where the MPLS connection information is evaluated and the MPLS packet is forwarded in accordance with this evaluation via the appropriate output of the switching network SN into the MPLS network.

The protection link PE can remain unused during this time. If necessary, however, it is also possible to supply special data (EXTRA TRAFFIC) to the switching device E during this time. In this case, the switching system S₀ of the switching device W assumes the positions 1 or 3. The special data are also transmitted in MPLS packets. The monitoring device ÜE₀ in the label switched router W applies control information to the MPLS packets in the same manner as has already been described in the case of those via the operating link WE₁ The link is monitored similarly. The special data used can be control data of a general type which can also be in the form of special traffic data.

The special data transmitted via the protection link can also be low-priority traffic which is transmitted in the network when there are sufficient resources available. The low-priority traffic is then automatically displaced by high-priority traffic being protection-switched in this case. In this case, the special data are not displaced in the protection switching case by switching the switching system S₀ in FIG. 2, but by prioritizing the high-priority traffic with respect to the low-priority special data in each transmission device.

In the text which follows, it is now assumed that the operating link WE₁ has failed. This is determined by the monitoring device ÜE₁, associated with this operating link WE₁, of the receiving label switched router E. The protection switching request is then transmitted to the relevant central controller and is stored there in the local priority table and in the global priority table.

As determined by the priorities stored in the global priority table, it is then determined whether requests with higher priority are still present. This could be, for example, the switch-over request of the user already discussed (FORCED SWITCH FOR WORKING ENTITY). If there are no requests with higher priority present, the switching system S₁ of the label switched router E is driven into the remaining operating state, as shown in FIG. 2. Thereafter, the protection switching protocol ES is then supplied to the label switched router W via the protection link PE. This protection switching protocol contains the information already discussed. The essential factor is that the local priority logic defines the arrangement of the information with respect to the protection switching request generated, and the global priority logic defines the position of the switching system S₀.

The monitoring device ÜE₀ of the label switched router W then takes over the protection switching protocol ES and supplies it to the central controller of the label switched router E. If no further requests with higher priority are present in the global priority table, the switching system S₁ is also correspondingly driven and set in this case. Furthermore, the switching system S₀ of the label switched router W is also switched over. The new status of the two switching systems S₀, S₁ is acknowledged to the label switched router E via the protection switching protocol ES, and updated in the global priority table there. The MPLS packets of the connection WT₁ are then supplied to the label switched router E via the protection link PE.

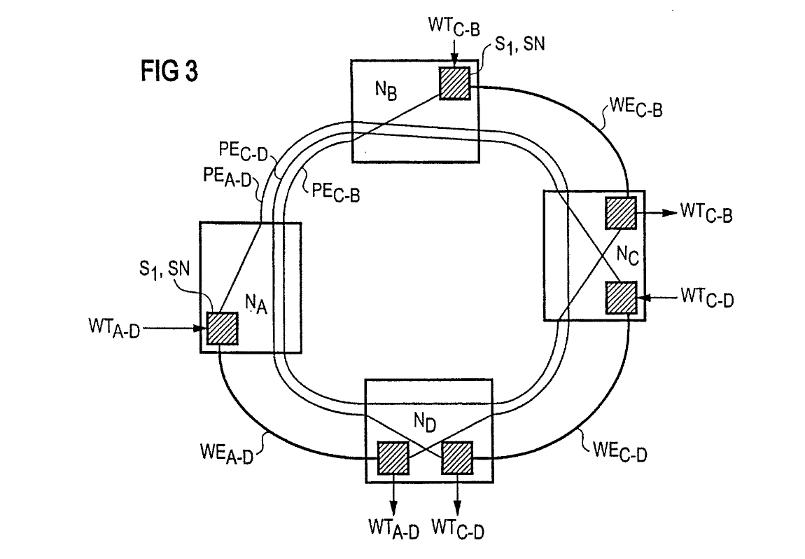

In FIG. 3 shows the ring configuration according to the invention. The switching devices are connected in such a manner in this case that the result is a closed ring. According to the present exemplary embodiment, this ring is to be configured from linear connection elements, as shown in FIG. 2 (1:1 structure).

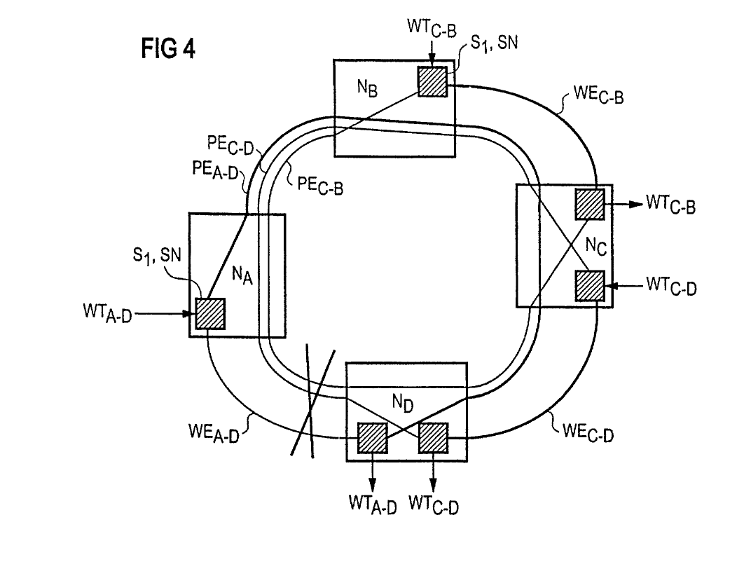

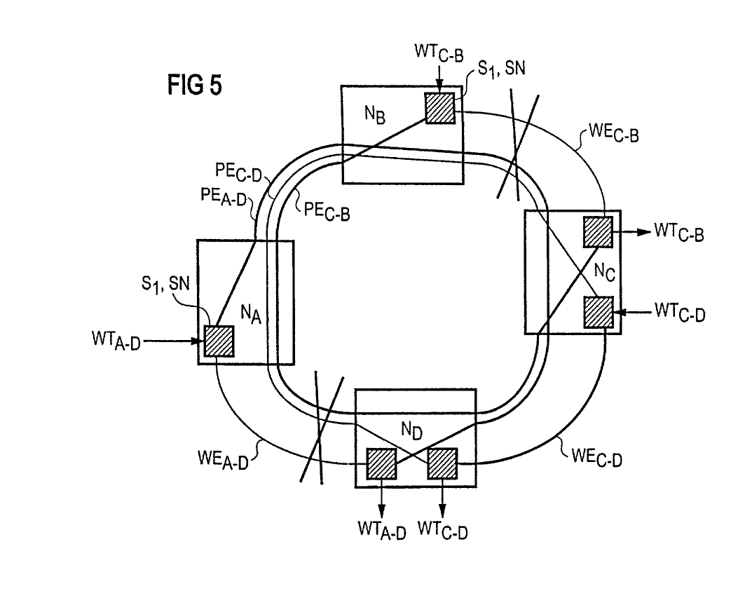

Accordingly, a multiplicity of label switched routers can be found in FIG. 3. These are the label switched routers N_{A}, N_{B}, N_{C} and N_{D}. Two of these label switched routers in each case terminate transmission sections. Using the example of label switched routers N_{A}, N_{D}, these are the operating link WE_{A-D} and the protection link PE_{A-D}. In the same manner, the two label switched routers N_{B}, N_{C} terminate the connection elements WE_{C-B}, PE_{C-B}. It is known that the latter are protection links assigned in each case. According to FIG. 3 (and also FIG. 4, FIG. 5), the operating links are emphasized by means of a thicker line, whereas the protection links are identified by a thin line.

Furthermore, switching devices S₁, SN which are identical to the switching devices shown according to FIG. 2 can be found in label switched routers. To simplify understanding, a more detailed disclosure is not given here. In label switched routers, central controllers with local and global priority tables are arranged which are not shown in greater detail here either. The operation has already been explained in greater detail in the case where a linear arrangement according to FIG. 2 is used.

It will now be assumed that a connection WT_{A-D} is to be conducted via the ring between two subscriber terminals. In this arrangement, the MPLS packets belonging to this connection are supplied to the label switched router N_{A} and conducted via the respectively active operating link WE_{A-D} to the label switched router N_{D}, where the MPLS packets belonging to the connection WT_{A-D} leave the ring again.

In FIG. 3, an arrow indicates the direction in which these MPLS packets enter the ring and leave it again. However, since this connection is a bidirectional connection, the MPLS packets belonging to the relevant reverse direction are conducted via the same connection elements. This means that the MPLS packets belonging to the reverse direction enter the ring via the label switched router N_{D}, are conducted via the connection WE_{A-D} to the label switched router N_{A} where they leave the ring again. For better clarity, however, only one direction will be illustrated in the text which follows. As a further embodiment of the invention, it is provided to arrange this configuration as a case of unidirectional transmission. This is easily possible since the transmission of MPLS packets is defined as being unidirectional in contrast to the transmission of ATM cells. However, this case of unidirectional transmission, too, requires a reverse direction and a protection switching protocol because the protection switching process is coordinated between transmitting and receiving end in the 1:1 architecture relevant in this case.

The same applies to the other connections WT_{C-B} and WT_{C-D} shown according to FIG. 3. The MPLS packets belonging to the three connections WT_{A-D}, WT_{C-B} and WT_{C-D} shown here are transmitted via the respectively active operating links WE_{A-D}, WE_{C-B} and WE_{C-D}. The associated protection links PE_{A-D}, PE_{C-B} and PE_{C-D} initially remain untouched.

FIG. 4 then shows how a fault in the ring is to be treated. This will be done using the example of the connection WT_{A-D}. It is thus assumed that the transmission section between the label switched routers N_{A} and N_{D} is affected by a fault. It is also assumed that this should be initially the only fault in the ring. The label switched router N_{A} is informed of the fault by exchanging the protection switching protocol ES over the protection link PE_{A-D}. As determined by the evaluation of the local and global priorities, the switching device S₁ of the label switched router N_{A} is now controlled into the remaining operating state. The MPLS packets belonging to the connection WE_{A-D} are then supplied via this protection link PE_{A-D} and via the label switched routers N_{B} and N_{C} to the label switched router N_{D} where they leave the ring.

According to one embodiment of the invention, a common transmission capacity is now reserved for the jointly used protection path for connection elements situated between two label switched routers. This is possible since it is assumed that one connection element of the ring is faulty. For example, it would be possible to assign in each case 140 Mbit/sec to the connections WT_{A-D}, WT_{C-B} and WT_{C-D}. For the connection element situated between label switched routers N_{A}, N_{B}, 140 Mbit/sec would thus be assigned for three protection links. This means that in the case of protection switching, 140 Mbit/s are available to one operating link on the associated protection link. Similar considerations apply to the connection elements situated between the label switched routers N_{B}, N_{C}. 140 Mbit/s would have to be reserved here in the same manner and, in the case of protection switching, a transmission capacity of 140 Mbit/s is also available in its full extent to one operating link on the associated protection link.

Such a procedure has the advantage, in particular, that, for each connection, fewer charges for transmission capacity should be registered (“shared protection”) It would be different in the case of “dedicated protection”. The saving effect is most advantageous in the case where a connection is established between two adjacent label switched routers. This is the case, for example, for the connection WT_{A-D} between the label switched routers N_{A}, N_{D}. The saving effect is greatest here because the associated protection links must be conducted to the label switched router N_{D} via the two further label switched routers N_{B}, N_{C}. The same applies to the other connections WT_{C-D} and WT_{C-D} shown.

If the label switched router N_{A} is arranged as switching level of a higher hierarchy level (such as, e.g., a core network), the saving effect would be the lowest compared with a “dedicated protection” configuration. In this case, any traffic of the remaining label switched routers would have to be conducted via this higher-level label switched router N_{A}. A medium saving effect would be obtained if each of the label switched routers were to communicate with each label switched router in the sense of a complete intermeshing.

Special data of a general type as explained in conjunction with FIG. 2 cannot be transmitted via the ring. In particular, these are the control data considered there. According to the invention, however, the special traffic data arranged as special data can be transmitted because of their own priority assigned to them.

Finally, a further fault case will be shown by way of example according to FIG. 5. In this case, an additional fault case is to occur on the communication link WE_{C-B} in addition to a simple fault as shown in FIG. 4. In this case, further protection switching protocols are exchanged. In this case, however, both the operating link and the protection link are faulty. Due to the joint reservation of transmission capacity for protection links, connections which are not influenced by the fault would also be affected in the case of protection switching of both affected operating links to the respective protection link. In the present case, these are the connections WT_{C-D}. Since a switch-over would not bring any advantage in this case as the protection link is also faulty, no switch-over will thus be performed in the case of the occurrence of double faults.

1. A method for the protection switching of transmission devices, comprising
at least two switching devices (N_{A}, N_{D}) which in each case terminate a transmission section formed of operating links (WE_{A-D}, WE_{D-A}) and/or protection links (PE_{A-D}, PE_{D-A}), and between which information is exchanged over this transmission section, wherein, in the case of a fault on the relevant transmission section, the information hitherto transmitted over this section is diverted, as necessary, to the protection link in accordance with the determination of priority criteria and logical connection information, characterized
in that the information is linked into MPLS packets, in that two oppositely directed unidirectional MPLS connections are logically associated with one another, the two oppositely directed MPLS connections in each case connecting the same switching devices,
in that a number of linear transmission sections are joined together so that a ring line system is formed, wherein operating link and protection link are conducted via different physical paths, and in that a multiplicity of protection links (PE_{A-D}, PE_{C-B}, PE_{C-D}) share a jointly reserved transmission capacity.

2. The method as claimed in claim 1, characterized in that a unidirectional ring line system is formed by using unidirectional switching devices, but the logical association of the two oppositely directed unidirectional MPLS connections is still retained.

3. The method as claimed in claim 1 or 2, characterized in that in the protection switching case, a protection switching request is generated to which other priorities are assigned.

4. The method as claimed in claim 1 to 3, characterized in that the logical connection information is the MPLS connection number (Label Value).

5. The method as claimed in claim 1 to 4, characterized in that local and global priority tables are provided in which the order of rank of the priorities is specified.

6. The method as claimed in one of the preceding claims, characterized in that when a protection switching request arrives in the receiving switching device, a protection switching protocol is generated which is supplied only once to the transmitting switching device via the protection link (PE).

7. The method as claimed in one of the preceding claims, characterized in that a total failure and degradation of an operating link are determined in the monitoring device of the receiving switching device.

8. The method as claimed in one of the preceding claims, characterized in that the switching devices are constructed as MPLS cross-connect switching systems.

9. The method as claimed in one of the preceding claims, characterized in that the protection switching, if necessary, is effected by driving a switching device (S₁) contained in the transmitting switching device and by using a selection device (SN) arranged in the receiving switching device.

10. The method as claimed in one of the preceding claims, characterized in that special data are transmitted via the protection link (PE) at times free of operating disturbances.

11. The method as claimed in one of the preceding claims, characterized in that the special data are arranged as low-priority traffic which are automatically displaced from said low-priority traffic in the case of protection switching of the high-priority traffic.

12. The method as claimed in one of the preceding claims, characterized in that the selection device (SN) is constructed as a switching network and/or as a simple switching element.

13. The method as claimed in one of the preceding claims, characterized in that the protection switching protocol is exchanged cyclically between the transmitting switching device and the receiving switching device.

14. The method as claimed in one of the preceding claims, characterized in that group protection switching is provided in that all MPLS connections conducted via the same physical path are logically combined to form a group, and for the group formed in this manner at least two protection switching connections are generated, in each case one of these protection switching connections being set up via an operating link (WE) and another one of these protection switching connections being set up via the protection link (PE).

15. The method as claimed in one of the preceding claims, characterized in that, in the case where group protection switching is provided, the monitoring devices (ÜE₀ . . . ÜEₙ) only monitor the at least two protection switching connections.

16. The method as claimed in one of the preceding claims, characterized in that the connections conducted via the at least one operating link (WE) and the connections conducted via the protection link (PE) are set up via an MPLS signaling protocol which also reserves bandwidth in the transmission devices and specifies the path of the operating link (WE₁) and of the protection link (PE).
